(19) United States
(12) Patent Application Publication
(10) Pub. No.: US 2004/0216666 A1
(43) Pub. Date: Nov. 4, 2004

(54) Device for supplying a process chamber with fluid media

(76) Inventors: Ulrich Hilburger, Erlangen (DE); Alexander Molchanov, Nurnberg (DE); Stefan Ossege, Erlangen (DE); Michael Miller, Spardorf (DE); Jochen Firedrich, Echental (DE); Gunther Wehrhan, Jena (DE)

Correspondence Address: Michael J. Striker, 103 East Neck Road, Huntington, NY, 11743, US

(21) Appl. No.: 10/647,407

(22) Filed: Aug. 25, 2003

(30) Foreign Application Priority Data
Aug. 26, 2002 (DE) 102 39 083.5

(51) Int. Cl. C23C 16/00

(52) U.S. Cl. 118/715

(57) ABSTRACT

With a device for supplying a process chamber with fluid media having at least one delivery line (17), that has a supply opening (18), and with sealing elements (15, 19) that are associated with the supply opening (18), a great deal of effort is required to load the process chamber and remove therefrom the material that is produced. Rapid and uncomplicated loading of the process chamber or removal therefrom of the material that is produced is enabled using tensioning mechanisms (30, 31) for holding the delivery line (17) against a receptacle (15) of the process chamber (10) that is associated with the supply opening (18).

The present invention relates to a device for supplying a process chamber with fluid media, having at least one delivery line that has a supply opening, and having sealing elements that are associated with the supply opening. The present invention also relates to the application of such a device for manufacturing products, in particular metal alloys or for growing crystals.

With modern industrial processes for manufacturing materials, such as metal alloys or for growing crystals, high process temperatures of 1500° Celsius and higher are required in some cases. In addition, it is often necessary to use reactive and/or corrosive gasses or carrier gasses. These various gasses must then be withdrawn. The process chamber that is used is often operated in a vacuum chamber. Tube connections that are stably joined via threaded connections are commonly used for supplying a process chamber. At high temperatures, however, thermal expansion of the threaded connections is problematic. In addition, in many production processes, the process chamber must be removed for loading, or to withdraw it from the vacuum chamber. When a threaded connection is used, extensive assembly work is required to accomplish this.

On the other hand, using open crucibles and gas lances results in contamination of the vacuum chamber and high gas consumption, because the entire vacuum chamber must be charged continually with reaction gasses.

Heating elements, sensors and vacuum components are often located in the vacuum chamber. These individual components also come in contact with the process gasses, which produces considerable stress on the individual components. In addition, temperature regulation is made markedly more difficult due to the pressure change that occurs in the process.

The object of the present invention is to create a device for supplying a process chamber with fluid media, the device allowing a process chamber to be reliably supplied with fluid media and making it possible to load the process chamber in a rapid and uncomplicated manner, or to remove the produced material therefrom.

This object is achieved using a device of the type mentioned initially, with which tensioning mechanisms are provided for holding the delivery line against a receptacle of the process chamber that is associated with the supply opening

Since, with this device, a threaded connection need not be loosened in order to load the process chamber or to remove the material that is produced, but, instead, it is only necessary to push the delivery line back against the tensile force of the tensioning mechanism, easy and simple handling is achieved with the device having the features of the present invention. A reliable supplying of fluid media is guaranteed through the supply opening and the receptacle associated with said supply opening via the delivery line. In this manner, it is possible to supply process gasses as well as carrier gasses. In addition, the required amount of gas can be withdrawn from the process chamber. If the process chamber is located in a vacuum chamber, the leakage rate is very low, and it depends on the tightness of the connection of the delivery line with the receptacle in the process chamber. In addition, said device for supplying fluid media is also suitable for use at high temperatures and with corrosive media if the proper material is selected, because sealing material that is susceptible to corrosion need not be used in high temperature ranges. On the other hand, the thermal expansion of the delivery line is reliably compensated for by the tensioning mechanisms at high temperatures as well.

The tensioning mechanisms can include at least one spring, in particular a helical spring. In this manner, the required tensioning force can be provided or adjusted in a simple manner.

It is an advantageously if it is possible to produce the tensioning force using ambient pressure. Since the stated process chamber is often operated in vacuum chambers, the difference between the chamber pressure and ambient pressure is often available, so that ambient pressure can be used in simple fashion to produce the tensioning force.

In addition, a guideway for the delivery lines in the tensioning direction has proven advantageous. Said guideway makes it easier to bring the supply opening together with the receptacle that is associated with it.

The delivery line can be connected to a receiving chamber that surrounds the process chamber in a gas-tight and axially displaceable manner at the end furthest from the supply opening with fastening elements for gas-tight mounting. Since the receiving chamber is usually cooled to acceptable temperatures, only minimal requirements are placed on the fastening elements and the mechanical elements for displacement at high process temperatures as well. For example, the furthest end can be fastened to a central body that is connected with a mounting flange by a bellows.

The central body can then be displaceably guided on at least one bolt that extends out of the mounting flange. The spring is then located between a spring hanger that is located on the bolt and the central body. This results in good guidance of the delivery line and holds it down securely. If three bolts are used, for example, this results in secure, parallel guidance, and tilting is reliably prevented.

In a further development, adjusting mechanisms are provided for adjusting the tensioning force. For example, the bolt can be a threaded bolt, and the spring hanger can be a nut located on the bolt. By screwing the nut on the threaded bolt, the spring force and, therefore, the tensioning force may be adjusted.

In another further development, the sealing mechanism is a press fit. Such a press fit has a suitable configuration of the frontal area that surrounds the supply opening and of the associated receptacle, said configuration having been designed to fit. For example, the press fit can include an end face of the delivery lines that is conical, frusto-conical or semi-spherical and that surrounds the supply opening, and the receptacle of the end face has a conical, frusto-conical or semi-spherical cavity associated with the end face. This provides the press fit with a self-centering effect. In any case, the end face and the receptacle should be suitably configured relative to each other, e.g., they should be machined to fit. It is also possible for the end face or the cavity to have a bezel and for the other element to have a flat surface.

In a particular embodiment of the invention, the delivery line can be composed of a temperature-resistant and corrosion-resistant material. Graphite is an example of suitable material.

In addition, an extension for the delivery line is advantageous. In this case, only the part of the delivery line that directly abuts the process chamber need be suitable for high temperatures and corrosive media, while the extension can be composed of simple steel or corrosion-resistant steel or stainless steel, which is simple to fasten. The delivery line and the extension can be screwed together, for example.

In a further development of the invention, blocking elements for the delivery line are provided. Preferably, the blocking elements block the fluid medium at the supply opening. In the blocked state, a large dead volume inside the delivery line is not exposed to contamination, particularly at high process temperatures. As a result, reaction products cannot separate out inside the delivery line.

One possible example of a blocking element is a needle valve, because it permits the fluid medium to be blocked or to flow through. A valve needle of the needle valve can have a conical, spherical or semi-spherical tip. A conical, spherical or semi-spherical valve seat should be located in the region of the supply opening, that is directed toward the valve needle and is associated with said valve needle. If elements for actuating the needle valve are located on the end of the delivery line that is furthest from the supply opening, they can also be located outside of a vacuum chamber, for example. In any case, the temperature stress and stress caused by corrosive media are less on the furthest end. Preferably, said actuating elements can be fastened to the central body.

If, in a further development, the valve needle is preloaded with a predetermined closing force on the valve seat, then a tight closing of the needle valve can be reliably achieved. It is also possible to limit the closing force using said preload. The weight of the valve needle can serve as the closing force, for example, if the valve needle is located vertically over the valve seat. Then, no elements are required for said closing force, which said elements would be subject to wear or corrosion.

A tension element that is connected with the valve needle can be provided. The valve needle may be actuated using said tension element. If it is possible to transmit a tensioning force but not a compressive force using said tension element, then the valve needle can indeed be retracted, but it cannot be closed using force that is stronger than the predetermined closing force. The tension element can have a first tensile part that is connected with the actuating element, and a second tensile part that is connected with the valve needle, and the two said tensile parts are interconnected in a limited area in a manner that allows them to be displaced toward each other. A simple configuration results when the first tension part and the second tension part are interconnected by an elongated hole and a driver.

In a further development, the tension element is connected with one end of a bellows, the other end of which is connected with the central body, and the one end is displaceable in the longitudinal direction of the tension element using the actuating element. In this manner, it is possible to guarantee the mimicking of displacement of the needle valve with reliable sealing that may be used in an ultra-high vacuum range as well.

The device according to the invention is particularly suitable for manufacturing products that must be treated with aggressive agents in a reaction chamber, such as metal alloys and pure or highly-pure—large-volume, in particular—crystals, such as those used as lenses, for example, to manufacture electronic components such as chips, in particular computer chips, telephone chips, etc. The present invention therefore relates to the application of the device for manufacturing said products as well.

An embodiment of the invention is explained in greater detail hereinbelow with reference to the drawing.

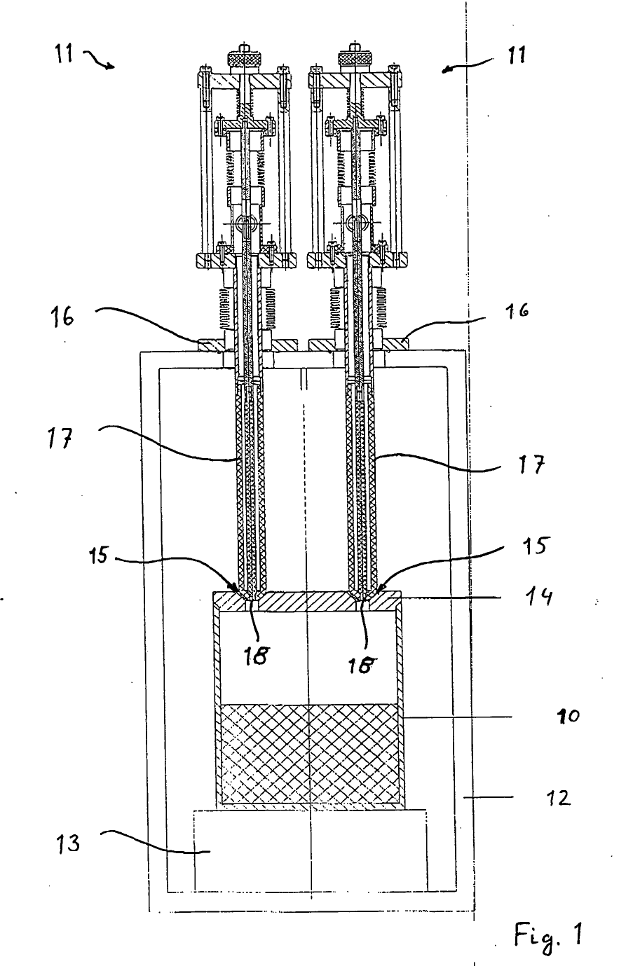

FIG. 1 is a schematic illustration of a device having the feature of the invention for supplying a process chamber,

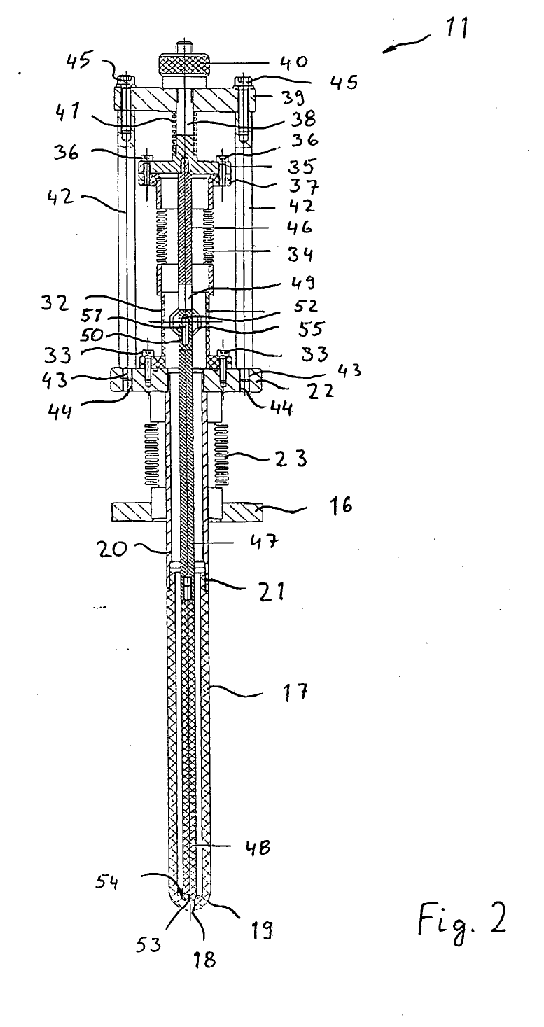

FIG. 2 is an enlarged illustration of the media supply device in FIG. 1, and

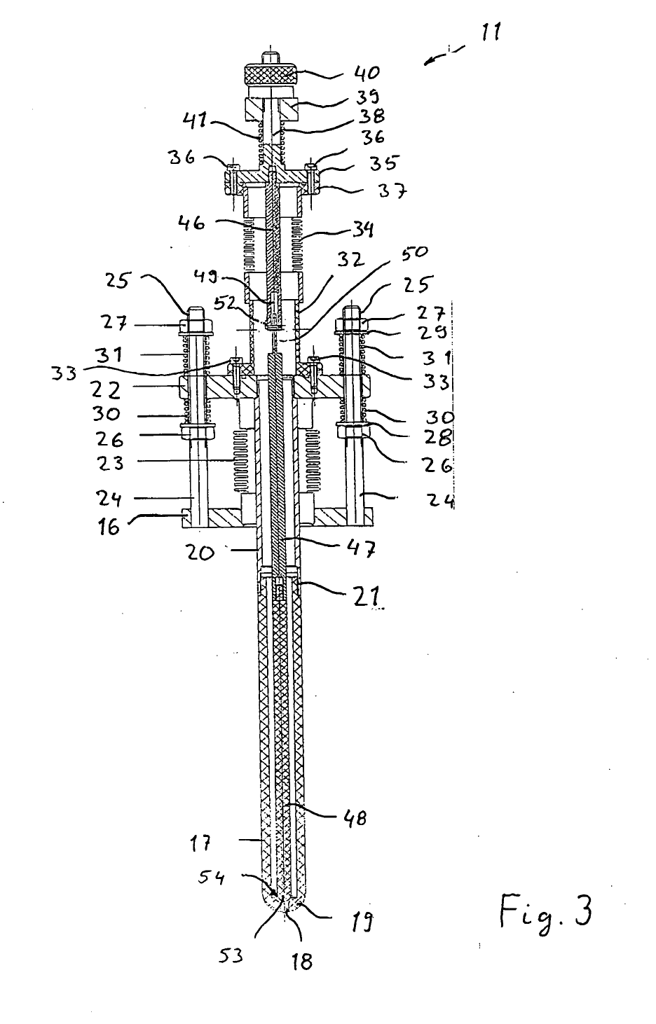

FIG. 3 is an illustration of the media supply device in FIG. 1 that is rotated by 90 degrees around the vertical axis.

FIG. 1 is a schematic illustration of a device having the features of the present invention for supplying a process chamber 10 with fluid media. Process chamber 10 is located in a vacuum chamber. Pumps for evacuating vacuum chamber 12 are not shown in the figure. In addition, a heating element and/or a thermal insulator 13 for process chamber 10 is located in vacuum chamber 12, if necessary. In FIG. 1, process chamber 10 has a cover 14 with two receptacles 15 on its top side.

Media supply devices 11 each have a mounting flange 16, with which they are mounted on vacuum chamber 12. In the embodiment shown, mounting flange 16 is a CF flange. KF flanges or other suitable fastening elements can be used as well, however. A suitable fluoroelastomer, such as Viton, can be used as sealing material to seal mounting flange 16 on the vacuum chamber 12. Viton provides a reliable sealing effect with good corrosion resistance at temperatures of up to approximately 200° C., and even up to 300° C. If vacuum chamber 12 has water cooling, for example, suitable temperature conditions for using Viton as sealing material can be created. It is also possible to use metal seals as sealing material, for example, such as copper seals or aluminum seals.

Media supply devices 11 also each have a delivery line 17, each of which has a supply opening 18 on its end face that is closest to receptacle 15. In FIG. 1, receptacles 15 are each shown as conical cavities, while the frontal areas of delivery lines 17 that are facing receptacles 15 are each spherical in shape. In this manner, a reliable sealing effect of the frontal areas in the recesses 15 is guaranteed, while ensuring suitable contact pressure. In the figure, a media supply device 11 serves to supply a reaction gas, while the other media supply device 11 serves to withdraw gas from process chamber 10. Delivery lines 17 are composed of a suitable, temperature-resistant and corrosion-resistant material. In the embodiment, delivery lines 17 are made of graphite.

FIG. 2 is an enlarged illustration of a media supply device 11 of FIG. 1, and FIG. 3 is a view of media supply device 11 in FIG. 2 that is rotated by 90 degrees around the vertical axis. Clearly shown in the figures is the fact that frontal region 19 surrounding supply opening 18 is configured hemispherical in shape. Delivery line 17 has an extension 20 on its end furthest from opening 18. In the embodiment shown, extension 20 is a stainless steel tube that is screwed together with delivery line 17 using a threaded connection 21. Extension 20 extends, displaceable in the longitudinal direction, through mounting flange 16, and is stably interconnected with a central body 22. With the embodiment shown, said connection is obtained using a threaded connection. Other connections are also possible, in principle, such as a vacuum-tight weld seam.

A bellows 23 surrounding extension 20 is located between mounting flange 16 and central body 22, said bellows being welded on each of its two ends in a vacuum-tight manner with mounting flange 16 and central body 22.

As shown clearly in FIG. 3, central body 22 is supported on mounting flange 16 in a manner that allows it to be displaced longitudinally on bolt 24. Two bolts 24 are provided in the embodiment shown. Three or four bolts can also be used, however. Bolts 24 then result in a largely secure guidance of delivery lines 17. In the embodiment, bolts 24 are configured as threaded bolts 24 that have an external thread 25 in the upper region in the figure. Nuts 26, 27 are screwed onto each external thread 25. A washer 28, 29 and a helical spring 30, 31 each are located between nuts 26, 27 and central body 22. Nuts 26, 27 and washers 28, 29 each serve jointly as spring hangers on which helical springs 30, 31 each bear. In this manner, central body 22 is supported on threaded bolt 24 with spring action and in longitudinally displaceable fashion.

A T-piece 32 with a branch 55 for the supply or withdrawal of the fluid medium is fastened on the end of central body 22 furthest from bellows 23. T-piece 32 is screwed together with central body 22 in a vacuum-tight manner using screws 33. A further bellows 34 is located on the end of T-piece 32 that is furthest from central body 22. The end of bellows 34 that is furthest from T-piece 32 is closed with a blind flange 35. Blind flange 35 is screwed together with a flange 37 of bellows 34 using screws 36. The side of blind flange 35 furthest from bellows 34 has a threaded bolt 38 that extends upward through a supporting plate 39 and engages with a knurled nut 40 above the supporting plate 39. Threaded bolt 38 is surrounded by a helical spring 41 between blind flange 35 and supporting plate 39. Supporting plate 39 is stably interconnected with central body 22 by two distance elements 42. Two distance rods 42 are used as distance elements 42, said distance rods having an external thread 43 on their end closest to central body 22, with which said external thread said distance rods are screwed together with internal threads 44 in central body 22. On their ends closest to supporting plate 39, distance rods 42 are each screwed together with supporting plate 39 using screws 45.

A first tension part 46 is fastened to, namely screwed together with, the side of blind flange 35 furthest from threaded bolt 38. The first tension part 46 is fastened in a longitudinally displaceable manner to a second tension part 47 on the end furthest from blind flange 35, the second tension part being connected with a valve needle 48 on its end furthest from first tension part 46. First tension part 46 has a groove 49 on its end closest to second tension part 47, in which said groove a segment 50 is located. Segment 50 has an elongated hole 51 that is engaged with a screw 52 that is screwed through the end of the first tension part 46 and extends over groove 49. Second tension part 47 is screwed together with valve needle 48 on its end furthest from first tension part 46. The end of valve needle 48 furthest from second tension part 47 has a spherical frontal area 53 that faces a conical valve seat 54 that surrounds supply opening 18. Valve needle 48, like delivery line 17, is also composed of a suitable, temperature-resistant and corrosion-resistant material. In the embodiment shown, valve needle 48 is composed of graphite. First tension part 46 and second tension part 47, on the other hand, are composed of a material having a certain elasticity. Stainless steel is used for first tension part 46 and second tension part 47.

If, after the two media supply devices 11 are placed on vacuum chamber 12, the vacuum chamber is evacuated, central body 22 and, therefore, delivery line 17, are pressed into the vacuum chamber until springs 30 compensate for the difference between the atmospheric pressure and the chamber pressure. By screwing nuts 27 onto threaded bolts 24, additional tensioning force may be exterted on central body 22 and, therefore, delivery line 17, using helical springs 31. In this manner, the particular delivery line 17 can be so loaded with a suitable tensioning force into the particular receptacle 15 that frontal area 19 seals tightly in receptacle 15 in a press fit. As a result, it is then possible to supply process chamber 10 with the particular fluid medium furnished by media supply device 11. In the case of thermal expansion or fluctuation of chamber pressure in vacuum chamber 12, delivery lines 17 can evade the tensioning force of the particular spring 31 without incurring damage.

The closing force of valve needle 48 is determined substantially by its weight and the weight of second tension part 47, since second tension part 47 is hung onto first tension part 46 by longitudinal hole 51 and screw 52. By turning knurled nut 40 on threaded bolt 38, valve needle 48 can be lowered into valve seat 54 via first tension part 46 and second tension part 47. After valve needle 48 rests with its entire weight in valve seat 54, turning knurled nut 44 further does not increase the closing force, however. Instead, screw 52 slides downward into longitudinal hole 51 in a nearly resistance-free manner. In this manner, damage to valve needle 48 or valve seat 54 caused by excessive closing force is prevented. Likewise, if a component of media supply device 11 undergoes thermal expansion, an undesirably great closing force is not obtained. Instead, valve needle 48 with second tension part 47 can deflect upward at any time into elongated hole 51.

With a further embodiment of media supply device having the features of the invention, oil-tight sliding elements are used to guide said media supply device into or through the vacuum chamber, for sealing purposes. Said sliding elements may be used when the requirements placed on the chamber pressure and the composition of residual gas in the chamber are minimal.

The device according to the invention is suitable in particular for growing large, homogeneous monocrystals, among other things. The crystal raw materials include raw materials, in particular, that contain the crystal material as well as scavengers that react, in a homogenizing phase, with any impurities that may be present, to form highly volatile substances. Preferable crystal materials are MgF₂, BaF₂, SrF₂, LiF and NaF, whereby CaF₂ is particularly preferred.

The device is therefore suitable as well for manufacturing optical components for DUV lithography and for manufacturing wafers coated with photoresist and, therefore, for manufacturing electronic devices. The present invention therefore also relates to the application of monocrystals produced using the device according to the invention in the manufacture of lenses, prisms, light-conducting rods, optical windows and optical devices for DUV lithography, in particular in the manufacture of stepping motors and excimer lasers and, therefore, in the manufacture of integrated circuits and electronic devices, such as computers that contain computer chips, as well as other electronic devices that contain chip-like integrated circuits.

In summary, the invention permits compensation for temperature-induced changes in the dimension of the process chambers without having to worry that the process chamber and/or the fluid delivery lines—that are typically formed by pipes—will be damaged. The ability of the delivery lines to be longitudinally displaced ensures that the tightness of the seating of the frontal area of the delivery lines at the edge of the supply openings of the process chamber is retained, even if the process chamber expands due to thermal causes. The preload force with which the delivery lines are pressed against the process chamber can be produced, in general, in various manners. One possibility is to provide a spring configuration that presses the delivery lines in the direction toward the process chamber. Such a spring configuration has the advantage that the preload force can remain nearly constant—or at least change within a non-substantial range—if process-induced changes occur to the pressure relationship between the vacuum chamber and the environment, and if the process chamber undergoes thermal expansion. A spring configuration having two elements that work in opposite directions permits a precise adjustment of the contact force of the delivery lines against the process chamber in the resting position, i.e., before evacuation of the vacuum chamber has started. Such an evacuation is a second possible source for a tensioning force that presses the delivery lines against the process chamber. Within the framework of the invention it is possible to produce the tensioning force simply using a spring configuration, in particular when a vacuum environment is not required to carry out the process, or it is not desired, or when the process even needs to take place in an overpressure environment. Embodiments are also feasible with which the tensioning force on the delivery lines is produced simply by a pressure differential between the outside environment and the vacuum chamber. In many cases, a combination of the two stated possibilities are used, i.e., a combination of a first preload force produced by a spring configuration, and a second preload force produced by a vacuum in the vacuum chamber.

Reference Numerals

| | |
|---|---|
| 10 | Process chamber |
| 11 | Media supply device |
| 12 | Vacuum chamber |
| 13 | Thermal insulation |
| 14 | Cover |
| 15 | Receptacle |
| 16 | Mounting flange |
| 17 | Delivery line |
| 18 | Supply opening |
| 19 | Frontal areas |
| 20 | Extension |
| 21 | Threaded connection |
| 22 | Central body |
| 23 | Bellows |
| 24 | Threaded bolt |
| 25 | External thread |
| 26 | Nut |
| 27 | Nut |
| 28 | Washer |
| 29 | Washer |
| 30 | Helical springs |
| 31 | Helical springs |
| 32 | T-piece |
| 33 | Screws |
| 34 | Bellows |
| 35 | Blind flange |
| 36 | Screw |
| 37 | Flange |
| 38 | Threaded bolt |
| 39 | Supporting plate |
| 40 | Knurled nut |
| 41 | Helical springs |
| 42 | Distance rod |
| 43 | External thread |
| 44 | Internal thread |
| 45 | Screw |
| 46 | First tension part |
| 47 | Second tension part |
| 48 | Valve needle |
| 49 | Groove |
| 50 | Segment |
| 51 | Elongated hole |
| 52 | Screw |
| 53 | Frontal area |
| 54 | Valve seat |
| 55 | Branch |

What is claimed is:

1. A device for supplying a process chamber with fluid media having at least one delivery line (17), that has a supply opening (18), and with sealing elements (15, 19) that are associated with the supply opening (18), characterized by tensioning mechanisms (30, 31) for holding the delivery line (17) against a receptacle (15) of the process chamber (10), said receptacle being associated with the supply opening (18).

2. The device as recited in claim 1,
wherein the tensioning mechanisms include at least one spring, in particular a helical spring (30, 31).

3. The device as recited in claim 1,
wherein the tensioning force is capable of being generated by ambient pressure.

4. The device as recited in claim 1, characterized by a guideway (24) for the delivery line (17) in the tensioning direction.

5. The device as recited in claim 3,
wherein the delivery line (17), at the end furthest from the supply opening (18), is interconnected in a gas-tight and axially displaceable manner, via fastening elements (16) for gas-tight fastening, to a receiving chamber (12) that encloses the process chamber (10).

6. The device as recited in claim 5,
wherein the furthest end is fastened to a central body (22) that is interconnected with a mounting flange (16) by a bellows (23).

7. The device as recited in claim 6,
wherein the central body (22) is displaceably guided on at least one of the bolts (24) that extends out of the mounting flange (16), and
wherein the spring (30, 31) is located between a spring hanger (26, 28; 27, 29) located on the bolt (24) and the central body (22).

8. A device as recited in claim 1, characterized by adjusting mechanisms (26, 27) for adjusting the tensioning force.

9. The device as recited in claim 8,
wherein the bolt is a threaded bolt (24), and the spring hanger is a nut (26, 27) that is located on the bolt (24).

10. The device as recited in claim 1, wherein the sealing element is a press fit (15, 19).

11. The device as recited in claim 10,
wherein the press fit (15, 19) has a conical, frusto-conical or semi-spherical end face (19) of the delivery line (17) that surrounds the supply opening (18), and
wherein the receptacle has a conical, frusto-conical or semi-spherical cavity (15) that is associated with the end face (19).

12. The device as recited in claim 1, wherein the delivery line (17) is composed of a temperature-resistant and corrosion-resistant material.

13. The device as recited in claim 12,
wherein the delivery line (17) is composed of graphite.

14. The device as recited in claim 1, characterized by an extension (20) for the delivery line (17).

15. The device as recited in claim 1, characterized by blocking elements (53, 54) for the delivery line (17).

16. The device as recited in claim 15,
wherein the blocking elements (53, 54) block the fluid medium at the supply opening (18).

17. The device as recited in claim 15,
wherein the blocking element is a needle valve (53, 54).

18. The device as recited in claim 17,
wherein a valve needle (48) of the needle valve has a conical, spherical or semi-spherical tip (53), and
wherein a conical, spherical or semi-spherical valve seat (54) is located in the region of the supply opening (18), facing the valve needle (48), and associated with said valve needle.

19. The device as recited in claim 17,
wherein actuating elements (40) for the needle valve (53, 54) are located on the end of the delivery line (17) that is furthest from the supply opening (18).

20. The device as recited in claim 19,
wherein the actuating elements (40) are fastened to the central body (22).

21. The device as recited in claim 18, wherein the valve needle (48) is preloaded against the valve seat (15) with a predetermined closing force.

22. The device as recited in claim 21,
wherein the weight of the valve needle (48) serves as closing force.

23. The device as recited in claim 18, characterized by a tension element that is interconnected with the valve needle (46, 47).

24. The device as recited in claim 23,
wherein it is possible to transmit a tensioning force, but not a compressive force, using the tension element (46, 47).

25. The device as recited in claim 24,
wherein the tension element has a first tension part (46) that is connected with the actuating element (40), and a second tension part (47) that is connected with the valve needle (48), and the two said tension parts are interconnected in a limited area (51) in a manner that allows them to be displaced toward each other.

26. The device as recited in claim 25,
wherein the first tension part (46) and the second tension part (47) are interconnected by an elongated hole (51) and a driver (52).

27. The device as recited in claim 23, wherein the tension element (46, 47) is interconnected with one end of a bellows (34), the other end of which is interconnected with the central body (22), and
wherein the one end is capable of being displaced by the actuating element (40) in the longitudinal direction of the tension element (46, 47).

28. An application of a device as recited in claim 1 for manufacturing products, in particular metal alloys or for growing crystals, for manufacturing lenses, prisms, light-conducting rods, optical windows and optical components for DUV photolithography, stepping motors, excimer lasers, wafers, computer chips as well as integrated circuits and electronic devices that contain such circuits and chips.

29. A process device, including
a tank with a tank wall,
a process container—with a container wall—located in the tank,
at least one pipe—that extends through an opening in the wall of the tank—for supplying or withdrawing a fluid medium into or out of the process container; the pipe having a pipe axis and a first bore hole in a first axial pipe end adjacent to the process container; the process container having a second bore hole in its container wall, the second bore hole being diametrically opposed to the first bore hole,
a sealing element that seals off the pipe, in a fluid-tight manner, from the opening in the tank wall,
a guideway element that moveably guides the pipe relative to the tank in the direction of the pipe axis, and
a tensile force-producing device for producing a tensile force that presses the pipe in the direction of its pipe axis against the wall of the process container.
